(19) United States
(12) Patent Application Publication
(10) Pub. No.: US 2024/0081031 A1
(43) Pub. Date: Mar. 7, 2024

(54) ENERGY STORAGE APPARATUS

(71) Applicant: LG ELECTRONICS INC., Seoul (KR)

(72) Inventors: Heejoong JANG, Seoul (KR); Dongkeun Yang, Seoul (KR); Hyoungsuk Woo, Seoul (KR)

(21) Appl. No.: 18/242,174

(22) Filed: Sep. 5, 2023

(30) Foreign Application Priority Data
Sep. 6, 2022 (KR) 10-2022-0112797

(51) Int. Cl. H05K 7/20; H01M 10/42; H01M 10/613; H01M 10/6568; H02J 7/00

(52) U.S. Cl. CPC H05K 7/20927; H01M 10/425; H01M 10/613; H01M 10/6568; H02J 7/0013; H05K 7/20254; H05K 7/20263; H02J 2207/20

(57) ABSTRACT

An energy storage apparatus may include: a battery pack having a plurality of battery cells; a power converter to charge or discharge the plurality of battery cells; a pump that supplies cooling water to the battery pack or the power converter; and a heat radiator that releases heat from cooling water flowing in the battery pack or the power converter. The power converter may include: a printed circuit board; a plurality of heating elements disposed on one side of the printed circuit board; and a cooling device placed in contact with the plurality of heating elements, and having at least one flow path formed therein for flow of the cooling water.

### CROSS-REFERENCE TO RELATED APPLICATION

This application claims priority under 35 U.S.C. § 119 to Korean Application No. 10-2022-0112797, filed on Sep. 6, 2022, whose entire disclosure is hereby incorporated by reference.

### BACKGROUND

### 1 Field

The present disclosure relates to an energy storage apparatus and, more particularly, to an energy storage apparatus that cools a battery by using cooling water.

### 2. Background

An energy storage apparatus may include a battery pack that has a plurality of battery cells connected in parallel or in series that repeatedly perform charging and discharging. The energy storage apparatus may be used as a source of power for motors of electric bicycles, scooters, electric vehicles, fork lifts, etc. The energy storage apparatus may be provided in a living space or office to store electricity generated in that space and to supply electric power back to the space.

The energy storage apparatus may include a power converter for converting electrical characteristics to charge or discharge a battery. The power converter may have a plurality of heating elements arranged on a circuit board. Field effect transistors (FET), which form an electric field by an applied voltage and control current by intensity of the electric field, may generate much heat and therefore may affect other semiconductor devices or circuit boards.

Accordingly, there is a need for a structure for cooling heating elements that generate a lot of heat. However, since a plurality of semiconductor devices are arranged on a circuit board, it is difficult to implement a cooling structure for only some heating elements.

Korean Patent Registration KR 10-2392920 B1, the subject matter of which is incorporated herein by reference, discloses a structure for cooling a battery cell.

### BRIEF DESCRIPTION OF THE DRAWINGS

Embodiments may be described in detail with reference to the following drawings in which like reference numerals refer to like elements and wherein:

FIG. 1 is a schematic system diagram of an energy storage apparatus according to an embodiment of the present disclosure;

FIG. 2 is a view of one side of heating elements mounted to a printed circuit board according to an embodiment of the present disclosure;

FIG. 3 is a view of the other side of heating elements mounted to a printed circuit board according to an embodiment of the present disclosure;

FIG. 4 is a schematic view for explaining a configuration of a cooling device mounted to heating elements according to an embodiment of the present disclosure;

FIG. 5 is view of one side of a cooling device mounted to heating elements according to an embodiment of the present disclosure;

FIG. 6 is a view for explaining how a clamping jig compresses a cooling device mounted to heating elements according to an embodiment of the present disclosure;

FIG. 7 is a view for explaining a cooling device mounted to heating elements, which has been altered in shape after being compressed by a clamping jig, according to an embodiment of the present disclosure;

FIG. 8 is a view of a heat sink provided at the heating elements and the cooling device of FIG. 7;

FIG. 9 is a perspective view of a cooling device mounted to a plurality of heating elements;

FIG. 10 is a plan view of a cooling device mounted to a plurality of heating elements;

FIG. 11 is a view for explaining how cooling water flows in a first cooling mode;

FIG. 12 is a view for explaining how cooling water flows in a second cooling mode; and

FIG. 13 is a view for explaining how cooling water flows in a preheating mode.

### DETAILED DESCRIPTION

Advantages and features of the present disclosure and methods for achieving them will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the present disclosure to those skilled in the art. The present disclosure is merely defined by the scope of the claims. Like reference numerals refer to like elements throughout the specification. The present disclosure will be described with reference to the drawings for explaining an energy storage apparatus according to embodiments of the present disclosure.

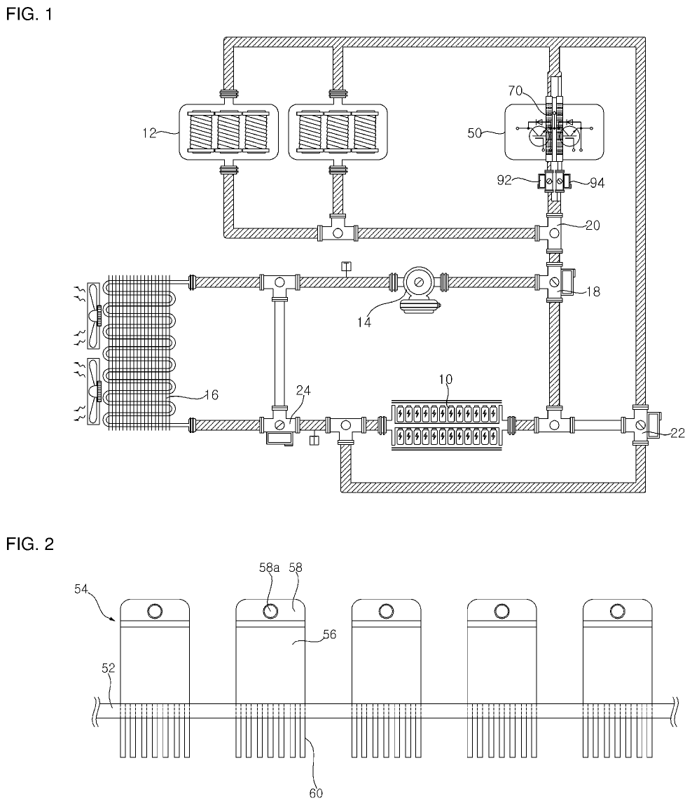

FIG. 1 shows that an energy storage apparatus may include at least one battery pack 10, a power converter 50 (PCS: Power Conditioning System) disposed inside a casing and for converting electrical characteristics to charge or discharge a battery, and a reactor 12 for stabilizing an abrupt change in current.

The energy storage apparatus may include a pump 14 for supplying cooling water (or a cooling liquid) to the battery pack 10 or the power converter 50, and a heat radiator 16 for dissipating heat from the cooling water that is caused to flow by the pump 14.

The energy storage apparatus may include a first switching valve 18 for selectively sending cooling water flowing from the pump 14 to the power converter 50 or to the battery pack 10, and a second switching valve 20 for selectively supplying cooling water flowing from the first switching valve 18 to the power converter 50 or to the reactor 12.

The energy storage apparatus may include a first bypass valve 22 for selectively sending or bypassing cooling water discharged from the power converter 50 or the reactor 12, and a second bypass valve 24 for selectively sending or bypassing cooling water to be supplied to the heat radiator 16.

The energy storage apparatus may include a cooling device 70 for cooling heating elements 54. The cooling device 70 may be included in the power converter 50.

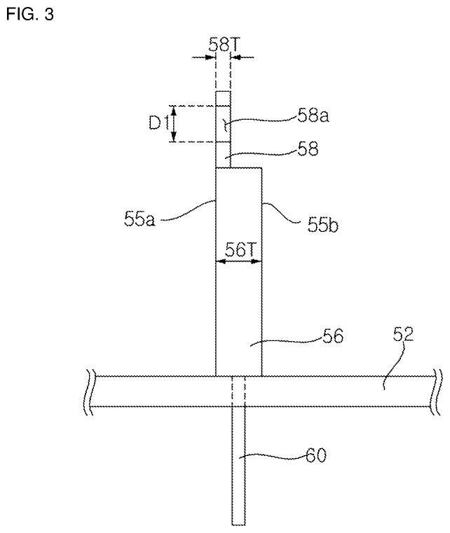

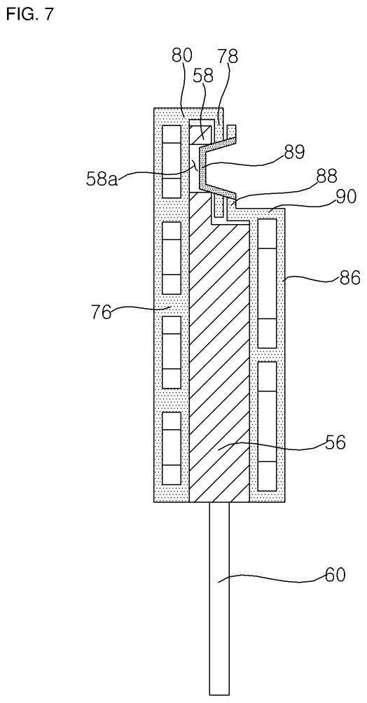

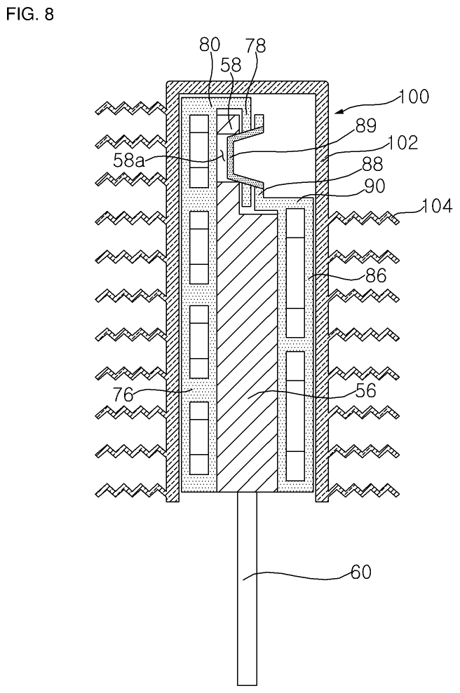

A configuration of the power converter 50 and a configuration of the cooling device 70 may be described in detail with reference to FIGS. 2 to 10.

The power converter 50 may include a circuit board 52 (or a printed board circuit board) and at least one heating element disposed on one side of the circuit board 52. The circuit board 52 may have a plate-like shape. A plurality of heating elements 54 may be disposed on one side of the circuit board 52. The plurality of heating elements 54 may be disposed on the same side of the printed circuit board 52.

Field effects transistors (FET) may be used as the heating elements 54. FET may form an electric field by an applied voltage and control current by intensity of the electric field.

The plurality of heating elements 54 may be spaced apart from each other in a same direction. Each of the plurality of heating elements 54 may include an element body 56 (or a body), a connector 60 to electrically connect the element body 56 and the circuit board 52, and an element header 58 (or a header) disposed above the element body 56. Most of the heat generated in the heating element may come from the element body 56.

Heat generated from the element body 56 may be released through a peripheral surface of the element body. The heat generated from the element body 56 may be released through the element header 58 disposed above the element body 56.

The element body 56 may be roughly rectangular in shape. The element header 58 may be disposed above the element body 56. A front-back thickness 58T of the element header 58 may be smaller than a front-back thickness 56T of the element body 56. The element header 58 may have a fixing hole 58a that is open in the front-back direction. Cooling plates 72 and 82 (described below) may be fixed to the heating elements 54. The cooling plates may be fixed through the fixing hole 58a.

The element body 56 and the element header 58 may form a continuous surface on a first side 55a of the heating element 54. The element body 56 and the element header 58 may form a discontinuous surface on a second side 55b of the heating element 54. The element body 56 and the element header 58 may be provided (or formed) in a step-like shape on the second side 55b of the heating element 54.

A first cooling plate 72 (described below) may be disposed to be in direct contact with the first side 55a of the heating element 54. A second cooling plate 82 (described below) may be disposed to be in direct contact with the second side 55b of the heating element 54.

The cooling device 70 may surround a periphery of the heating element 54. The cooling device 70 may include cooling plates 72 and 82 in which a first flow path 74a and a second flow path 74b are provided, and regulating valves 92 and 94 that enable a flow of cooling water in the first flow path 74a or the second flow path 74b. The cooling plates 72 and 82 may be provided around the heating element(s) 54.

The regulating valves may include a first regulating valve 92 for regulating the flow of cooling water to the first flow path 74a, and a second regulating valve 94 for regulating the flow of cooling water to the second flow path 74b.

The first regulating valve 92 and the second regulating valve 94 may operate individually (or separately). Thus, the cooling water (caused to flow by the pump 14) may be supplied to both the first flow path 74a and the second flow path 74b, or to either the first flow path 74a or the second flow path 74b.

The cooling plates may include the first cooling plate 72 disposed in direct contact with one side of the heating elements 54, and the second cooling plate 74 disposed in direct contact with the other side of the heating elements 54.

The first cooling plate 72 may include a first plate 76 and a first fixing plate 78 for attaching the first plate 76 securely to the heating elements 54. The first cooling plate 72 may include a first connecting plate 80 that connects an upper end of the first plate 76 and an upper end of the first fixing plate 78.

The second cooling plate 82 may include a second plate 86 and a second fixing plate 88 for attaching the second plate 86 securely to the heating elements 54. The second cooling plate 82 may include a second connecting plate 90 that connects an upper end of the second plate 86 and an upper end of the second fixing plate 88.

Each of the first plate 76 and the second plate 86 are disposed in direct contact with the heating elements 54. The first plate 76 and the second plate 86 are disposed in opposite directions from the heating elements 54.

A vertical length 76H of the first plate 76 may be greater than a vertical length 86H of the second plate 86. The first plate 76 may be disposed in direct contact with the element body 56 and the element header 58. The second plate 86 may be disposed in direct contact with the element body 56.

Each of the first plate 76 and the second plate 86 are formed to have the first flow path 74a and the second flow path 74b disposed below the first flow path 74a. The first flow path 74a and the second flow path 74b disposed (or formed) in the first plate 76 may branch off into a plurality of flow paths that are vertically spaced apart from each other.

The first flow path 74a formed in the first plate 76 may branch off into a plurality of flow paths that are vertically spaced apart. The first flow path 74a formed in the first plate 76 may branch off into a first upper flow path 74a1 and a first lower flow path 74a2. In the first plate 76, the first flow path 74a may branch off at an inlet end into the first upper flow path 74a1 and the first lower flow path 74a2, and the first upper flow path 74a1 and the first lower flow path 74a2 may join at an outlet end of the first flow path 74a.

The second flow path 74b formed in the first plate 76 may branch off into a second upper flow path 74b1 and a second lower flow path 74b2. The second flow path 74b may branch off at an inlet end into the second upper flow path 74b1 and the second lower flow path 74b2, and the second upper flow path 74b1 and the second lower flow path 74b2 may join at an outlet end of the second flow path 74b.

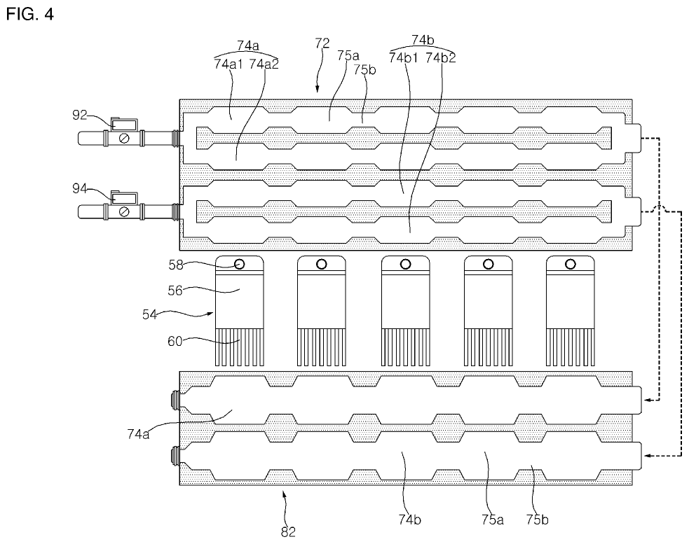

The first flow path 74a and the second flow path 74b formed in the first plate 76 may have a shape in which their cross-sectional area is enlarged or reduced repeatedly in the flow direction of cooling water. FIG. 4 shows that each of the first flow path 74a and the second flow path 74b may separately include an enlarged portion 75a where the flow path has a larger cross-sectional area, and a reduced portion 75b where the flow path has a smaller cross-sectional area.

Each of the enlarged portion 75a and the reduced portion 75b may be of a given length. The enlarged portion 75a may be disposed in an area where a heating element 54 is disposed. The reduced portion 75b may be disposed in a space between two heating elements that are spaced apart from each other.

Each of the first plate 76 and the second plate 86 are separately disposed in direct contact with the plurality of heating elements 54 which are spaced apart in the same direction.

The cooling plates 72 and 82 may include a bending plate 91 (or bending structure) that connects end portions of the first cooling plate 72 and the second cooling plate 82. The bending plate 91 may have a bending structure whose shape may be altered.

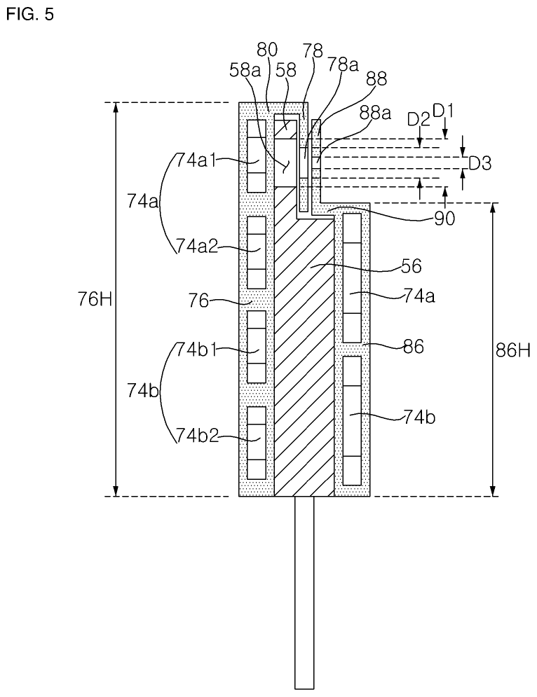

The first fixing plate 78 may be spaced apart from the first plate 76. The first fixing plate 78 and the first plate 76 may be disposed in different directions with respect to the element header 58. FIG. 5 shows that the first fixing plate 78, the first plate 76, and the first connecting plate 80 may be disposed to surround the element header 58.

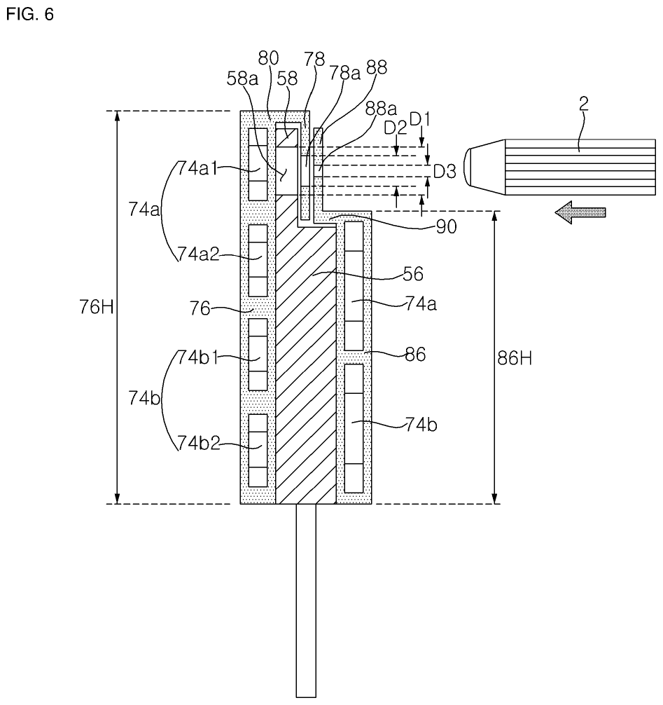

The first fixing plate 78 may have a first hole 78a. The first hole 78a may be disposed to correspond to a position of the fixing hole 58a formed in the element header 58. FIG. 6 shows that the diameter D2 of the first hole 78a may be smaller than the diameter D1 of the fixing hole 58a.

The second fixing plate 88 may be disposed to face the first fixing plate 78. The second fixing plate 88 may be disposed to face the second plate 86. The second connecting plate 90 may connect a lower end of the second fixing plate 88 and an upper end of the second plate 86. The second connecting plate 90 may be disposed above the element body 56.

When the cooling plates 72 and 82 are mounted to the heating elements 54, the first fixing plate 78 and the second fixing plate 88 may be disposed to face each other. The phrase “when the cooling plates 72 and 82 are mounted to the heating elements 54” may refer to when the first plate 76 is in contact with one side of the heating elements 54 and the second plate 86 is in contact with the other side of the heating elements 54.

The second fixing plate 88 may have a second hole 88a. When the cooling plates 72 and 82 are mounted to the heating element 54, the second hole 88a may be disposed to correspond to a position of the first hole 78a. FIG. 5 shows the diameter D3 of the second hole 88a may be smaller than the diameter D2 of the first hole 78a.

The first fixing plate 78 and the second fixing plate 88 may be altered in shape when a given pressure or more is applied.

A method of fixing the cooling plates 72 and 82 to the heating element 54 may be described. By altering the shapes of the first fixing plate 78 and the second fixing plate 88, the cooling plates 72 and 82 may be fixed to the heating element 54.

A clamping jig 2 may be used to compress parts where the first hole 78a (of the first fixing plate 78) and the second hole 88a (of the second fixing plate 88) are formed. As shown in FIG. 6, while the cooling plates 72 and 82 are mounted to the heating element 54, parts where the first hole 78a and the second hole 88a are provided may be pressed with the clamping jig 2. In this example, the parts where the first hole 78a and the second hole 88a are provided may be altered in shape.

When the clamping jig 2 compresses one side of the second fixing plate 88, the second fixing plate 88 may protrude in the direction of the fixing hole 58a based on a high pressure. In this example, the second fixing plate 88 may protrude in the direction of the fixing hole 58a by penetrating the first fixing plate 78. A shape altering portion 89 of the second fixing plate 88 may be inserted into the fixing hole 58a. The shape altering portion 89 (of the second fixing plate 88) may be disposed to be attached securely to the inside of the fixing hole 58a.

The cooling device 70 may include a heat sink 100 that is disposed around the cooling plates 72 and 82 and that releases heat transferred from the cooling plates 72 and 82. The heat sink 100 may have a 11-shape when viewed from a side.

The heat sink 100 may include a contact plate 102 disposed in contact with the periphery of the cooling plates 72 and 82, and a plurality of heat radiating fins 104 that protrudes from an outer periphery of the contact plate 102. The plurality of heat radiating fins 104 may be disposed in an area where the contact plate 102 comes into contact with the first plate 76 or the second plate 86. The plurality of heat radiating fins 104 may protrude outward in a zig-zag manner.

The contact plate 102 may be disposed to be attached securely to the cooling plates 72 and 82. The contact plate 102 may cause the cooling plates 72 and 82 to be attached securely to the heating element 54. When the heat sink 100 is disposed on the outer periphery of the cooling plates 72 and 82, fixing strength of the cooling plates 72 and 82 to the heating element 54 may be enhanced.

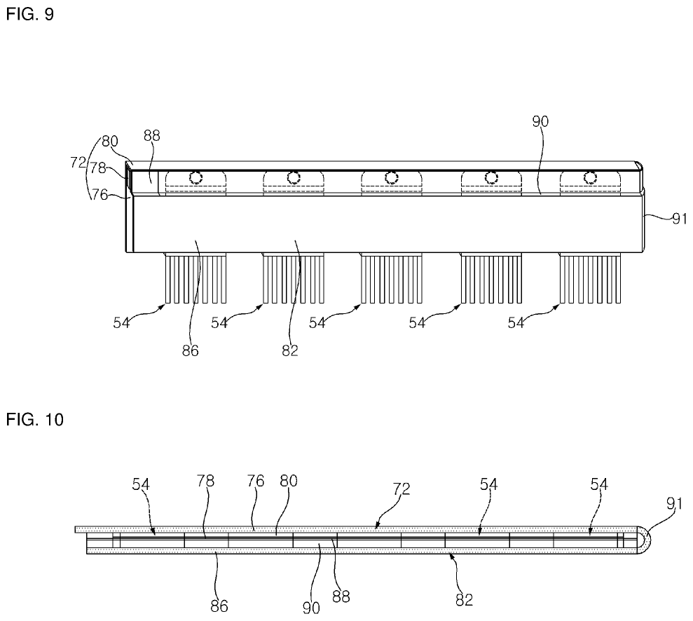

The cooling plates 72 and 82 may be disposed to surround each of the plurality of heating elements 54. Referring to FIGS. 9 and 10, the plurality of heating elements 54 are spaced apart in the same direction. Referring to FIGS. 9 and 10, the plurality of heating elements 54 may be made equal in size.

The cooling plates 72 and 82 may be disposed to be in direct contact with each of the plurality of heating elements 54 which are spaced apart in the same direction. The cooling plates 72 and 82 may be disposed to be fixed to each of the plurality of heating elements 54.

The enlarged portions 75a of the first flow path 74a and the second flow path 74b (formed in the cooling plates 72 and 82) are disposed where they come into contact with the heating elements 54. The reduced portions 75b of the first flow path 74a and the second flow path 74b (formed in the cooling plates 72 and 82) are disposed in gaps between the plurality of heating elements 54.

<Operation Mode>

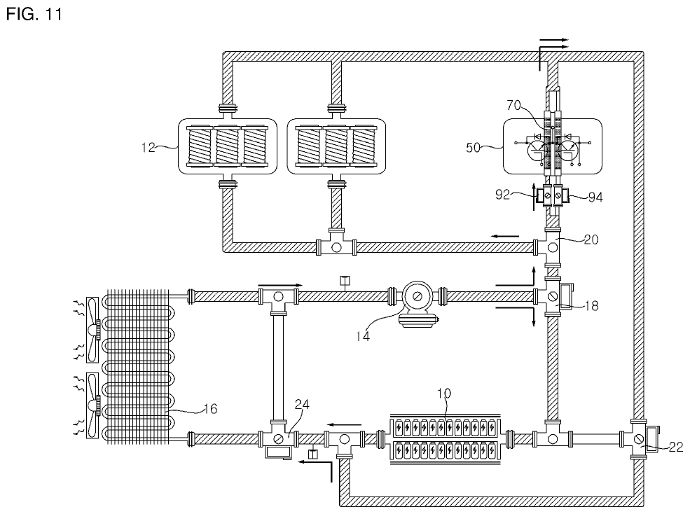

An energy storage apparatus of the present disclosure may operate in a plurality of modes. Referring to FIGS. 11 to 13, the energy storage apparatus may operate in a first cooling mode CM1, a second cooling mode CM2, and a preheating mode HM.

The first cooling mode CM1 and the second cooling mode CM2 may be differentiated depending on a temperature of cooling water discharged from the power converter 50 or a temperature of the power converter 50.

If the temperature of the power converter 50 is less than a set temperature, the first cooling mode CM1 may be performed to supply cooling water to the first flow path 74a alone (i.e., without supplying to the second flow path 74b). If the temperature of the power converter 50 is greater than or equal to the set temperature, the second cooling mode CM2 may be performed to supply cooling water to both the first flow path 74a and the second flow path 74b.

In the first cooling mode CM1, the first regulating valve 92 and the second regulating valve 94 may selectively open either the first flow path 74a and the second flow path 74b. Referring to FIG. 11, the first regulating valve 92 opens the first flow path 74a, and the second regulating valve 94 closes the second flow path 74b. Accordingly, the cooling water caused to flow by the pump 14 may pass through the power converter 50 only via the first flow path 74a.

As the pump 14 is actuated, cooling water may flow to cool the power converter 50 or the battery pack 10. In this example, a coolant (or liquid) flowing to the power converter 50 may pass only via the first flow path 74a. The cooling water may absorb the heat generated from the element body 56 and the element header 58 in the first plate 76 and the heat generated from the element body 56 in the second plate 86.

After exchanging heat in the power converter 50 or the battery pack 10, the cooling water may flow to the heat radiator 16 and be cooled. Incidentally, unlike in FIG. 11, the first regulating valve 92 may close the first flow path 74a and the second regulating valve 94 may open the second flow path 74b.

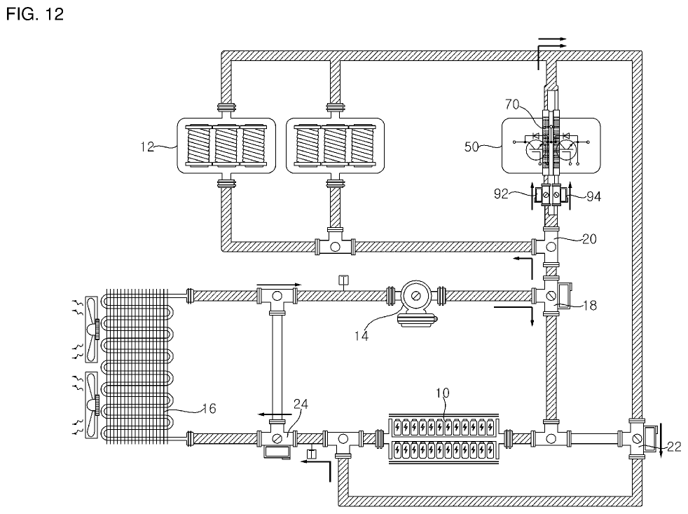

FIG. 12 shows that in the second cooling mode CM2, cooling water may be sent to the first flow path 74a and the second flow path 74b. The first regulating valve 92 and the second regulating valve 94 may open the first flow path 74a and the second flow path 74b, respectively, so that the cooling water flows in the first flow path 74a and the second flow path 74b.

The cooling water caused to flow by the pump 14 may flow in the first flow path 74a and the second flow path 74b, and exchange heat across the entire area of the heating elements 54. After exchanging heat in the power converter 50, the cooling water may be cooled in the heat radiator 16.

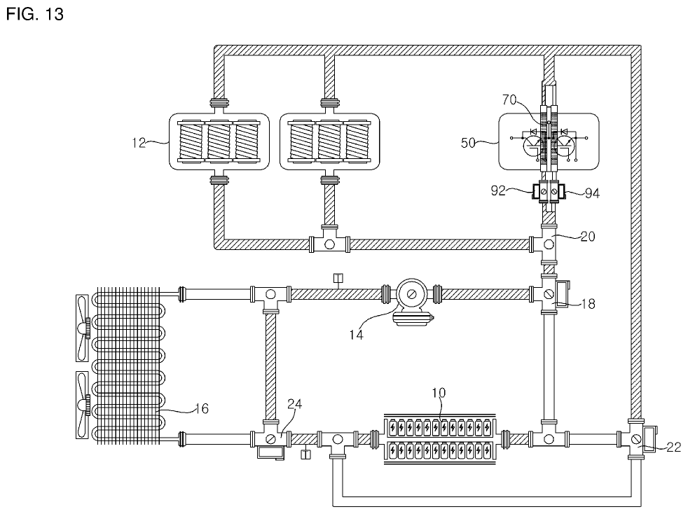

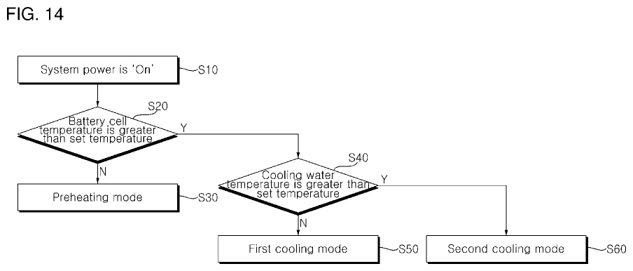

FIG. 13 shows that in the preheating mode HM, cooling water is not sent to the heat radiator 16. The heat radiator 16 may not be actuated. In the preheating mode HM, the first regulating valve 92 and the second regulating valve 94 may open both of the first flow path 74a and the second flow path 74b, respectively. As much heat generated from the heating elements 54 as possible may be absorbed and supplied to the plurality of battery cells disposed in the battery pack 10. The second bypass valve 24 may bypass the cooling water to be supplied to the heat radiator 16 and supplies it to the pump 14.

<Control>

A method of controlling an energy storage apparatus according to the present disclosure may be described with reference to FIG. 14.

The method of controlling an energy storage apparatus may include activating system power (S10). Afterwards, the energy storage apparatus compares the temperature of a plurality of battery cells included in the battery pack 12 (S20). The preheating mode HM or the cooling mode CM1 or CM2 may be performed based on the temperatures of the plurality of battery cells. If the temperature of the battery cells is less than or equal to a set temperature, the preheating mode HM may be performed (S30).

When the temperature of the battery cells is greater than the set temperature, the first cooling mode S50 or the second cooling mode S60 may be performed.

When the temperature of the battery cells is greater than the set temperature, it is compared with the temperature of cooling water discharged from the power converter 50 (S40). The first cooling mode (S50) or the second cooling mode (S60) may be performed based on the temperature of the discharged cooling water.

When the temperature of cooling water discharged from the power converter 50 is less than or equal to a set temperature, the first cooling mode CM1 may be performed (S50). When the temperature of cooling water discharged from the power converter 50 is greater than the set temperature, the second cooling mode CM2 may be performed (S60).

The present disclosure provides an energy storage apparatus that lowers temperature of a power converter by directly cooling heating elements which are the components of the power converter that generate the most heat.

The present disclosure provides an energy storage apparatus that improves heat exchange between heating elements and a cooling device.

The present disclosure provides an energy storage apparatus that allows for easy mounting of a cooling device to heating elements. Furthermore, the present disclosure provides an energy storage apparatus that allows a cooling device mounted to heating elements to be fixed in place.

The present disclosure provides an energy storage apparatus that allows a cooling device to be stably placed at heating elements and improve performance of the cooling device.

To accomplish the above aspects, an exemplary embodiment of the present disclosure provides an energy storage apparatus including: a battery pack with a plurality of battery cells placed therein; a power converter for converting electrical characteristics to charge or discharge the plurality of battery cells; a pump that supplies cooling water to the battery pack or the power converter; and a heat radiator that releases heat from cooling water flowing from the battery pack or the power converter, wherein the power converter includes: a printed circuit board; a plurality of heating elements disposed on one side of the printed circuit board, that generates heat; and a cooling device placed in contact with the plurality of heating elements, with at least one flow path formed therein where cooling water flows. Thus, the heat generated from the heating elements may be absorbed directly by the cooling device.

Each of the plurality of heating elements may include: an element body; a connector that electrically connects the element body and the circuit board; and an element header disposed above the element body, wherein the cooling device is placed in contact with at least two sides of the element body. Thus, the cooling device is able to absorb heat from a plurality of sides of the heating elements.

The cooling device may include: a first cooling plate disposed on one side of the heating elements; and a second cooling plate disposed on the other side of the heating elements, wherein each of the first and second cooling plates is formed with at least one flow path in which cooling water flows. Thus, the cooling water flowing in the first cooling plate and the second cooling plate may absorb the heat generated from the heating elements.

A flow path formed in each of the first and second cooling plates may have a shape in which a cross-sectional area thereof is enlarged or reduced repeatedly in the direction of cooling water flow.

The cooling device may include a bending plate that connects the first cooling plate and the second cooling plate, wherein the bending plate connects a flow path formed in the first cooling plate and a flow path formed in the second cooling plate. Thus, the cooling water flowing in the first cooling plate may flow to the second cooling plate.

Each of the plurality of heating elements may include: an element body; a connector that electrically connects the element body and the circuit board; and an element header disposed above the element body, wherein the element body and the element header form a continuous surface on a first side of the heating element, and the element body and the element header form a discontinuous surface on a second side of the heating element. Thus, the second side may be formed with a stepped portion between the element body and the element header.

The cooling device may include: a first cooling plate placed in contact with one side of the heating elements; and a second cooling plate placed in contact with the other side of the heating elements, wherein the first cooling plate is placed in contact with the element body and the element header, and the second cooling plate is placed in contact with the element body. Thus, the contact area of the first cooling plate may be enlarged.

The first cooling plate may include: a first plate formed with a flow path in which cooling water flows; and a first fixing plate for attaching the first plate securely to the heating elements, and the second cooling plate may include: a second plate formed with a flow path in which cooling water flows; and a second fixing plate for attaching the second plate securely to the heating elements. Thus, the cooling device may be fixed to the heating elements.

The first plate and the second plate may be disposed in different directions with respect to the heating elements, and the first fixing plate and the second fixing plate may be disposed in the same direction with respect to the heating elements. Thus, the first fixing plate and the second fixing plate may be placed in contact with each other.

A vertical length of the first plate may be greater than a vertical length of the second plate. Thus, heat exchange at the first plate may be improved.

The first plate and the second plate each may be formed with a first flow path and a second flow path disposed below the first flow path, and each of the first and second flow paths formed in the first plate may include a plurality of flow paths that are spaced out vertically.

The element header may be formed with a fixing hole, and the first fixing plate may be formed with a first hole corresponding in position to the fixing hole.

The second fixing plate may be formed with a second hole corresponding in position to the first hole, wherein the diameter of the second hole is smaller than the diameter of the fixing hole or the diameter of the first hole. Thus, when part of the second fixing plate is altered in shape, it may be inserted into the fixing hole.

When the cooling plates are mounted to the heating elements, the first fixing plate and the second fixing plate may be disposed to face each other, and the second hole may be disposed to correspond in position to the first hole. Thus, the first fixing plate and the second fixing plate may be easily altered in shape at a position corresponding to the fixing hole.

The first fixing plate and the second fixing plate may be altered in shape when a given pressure or more is applied. Thus, part of them may be inserted into the fixing hole.

While the cooling device is mounted to the heating element, a portion of the first fixing plate having the first hole and a portion of the second fixing plate having the second hole are pressed withe a clamping jig to move the portion of the first fixing plate into the fixing hole. Thus, the first fixing plate and the second fixing plate may be altered in shape.

The cooling device may include: a cooling plate placed in contact with each of the plurality of heating elements, with a flow path formed therein where cooling water flows; and a heat sink that is disposed around the cooling plates and releases heat transferred from the cooling plate. Thus, the heat absorbed from the cooling plate may be released.

The cooling plate may include: a first cooling plate placed in contact with one side of each of the plurality of heating elements; and a second cooling plate placed in contact with the other side of each of the plurality of heating elements, and the heat sink may be disposed to be attached securely to the first cooling plate and the second cooling plate. Thus, the heat sink may allow the cooling plate to be fixed in place.

The heat sink may include: a contact plate placed in contact with the periphery of the cooling plate; and a plurality of heat radiating fins protruding from the outer periphery of the contact plate. Thus, the heat absorbed by the contact plate may be released through the radiating fins.

The first cooling plate may include: a first plate formed with a flow path in which cooling water flows; and a first fixing plate for attaching the first plate securely to the heating elements, and the second cooling plate may include: a second plate formed with a flow path in which cooling water flows; and a second fixing plate for attaching the second plate securely to the heating elements, wherein the plurality of heat radiating fins are disposed in an area where the contact plate comes into contact with the first plate or the second plate.

Another embodiment of the present disclosure provides an energy storage apparatus including: a battery pack with a plurality of battery cells placed therein; a power converter for converting electrical characteristics to charge or discharge the plurality of battery cells; a pump that supplies cooling water to the battery pack or the power converter; and a heat radiator that releases heat from cooling water flowing in the battery pack or the power converter, wherein the power converter includes: a printed circuit board; a plurality of heating elements disposed on one side of the printed circuit board, that generates heat; a cooling plate placed in contact with the plurality of heating elements, with at least one flow path formed therein where cooling water flows; and a heat sink disposed on the outer periphery of the cooling plate, for releasing heat transferred from the cooling plate, wherein the heat sink attaches the cooling plate securely to the heating elements. Thus, the cooling device may cool the heat generated from the heating elements through the cooling plate and the heat sink, and the heat sink may allow the cooling plate to be fixed in place.

An energy storage apparatus of the present disclosure may offer one or more of the following effects.

First, heat generated from heating elements may be quickly cooled since a cooling device (in which cooling water flows) is disposed in direct contact with the heating elements.

Second, the cooling device may include a cooling plate that forms a plurality of flow paths, and the shape or configuration of the cooling plate and the shape of the flow paths (formed in the cooling plate) allow the cooling plate to effectively cool the heat generated from the heating elements.

Third, the cooling plate can be fixed in place to the heating elements by mounting a fixing plate to element headers of the heating elements and partially altering its shape.

Fourth, the present disclosure is advantageous in that a heat sink may dissipate heat generated from the cooling plate and allows the cooling plate to be fixed in place, thereby making the cooling device stably provided and improving its cooling performance.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section could be termed a second element, component, region, layer or section without departing from the teachings of the present invention.

Spatially relative terms, such as “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to cross-section illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An energy storage apparatus comprising:
a battery pack configured to support a plurality of battery cells;
a power converter configured to charge or discharge the plurality of battery cells;
a pump configured to provide a cooling liquid to the battery pack or the power converter; and
a heat radiator configured to dissipate heat from the cooling liquid flowing from the battery pack or the power converter,
wherein the power converter includes:
a circuit board;
a plurality of heating elements disposed on a side of the circuit board; and
a cooling device disposed to contact with the plurality of heating elements, and having at least one flow path configured to allow flow of the cooling liquid.

2. The energy storage apparatus of claim 1, wherein each of the plurality of heating elements includes:
a body;
a connector that electrically connects the body to the circuit board; and
a header disposed above the body such that the body is between the header and the circuit board,
wherein the cooling device is to contact at least two sides of the body.

3. The energy storage apparatus of claim 2, wherein the cooling device includes:
a first cooling plate disposed on a first side of the heating elements; and
a second cooling plate disposed on a second side of the heating elements,
wherein each of the first and second cooling plates separately has at least one flow path to allow flow of the cooling liquid.

4. The energy storage apparatus of claim 3, wherein the flow path provided by each of the first and second cooling plates has a shape in which a cross-sectional area is enlarged and reduced repeatedly in a direction of flow of the cooling liquid.

5. The energy storage apparatus of claim 3, wherein the cooling device includes a bending structure that connects the first cooling plate to the second cooling plate,
wherein the bending structure connects the flow path provided by the first cooling plate to the flow path provided by the second cooling plate.

6. The energy storage apparatus of claim 1, wherein each of the plurality of heating elements includes:
a body;
a connector that electrically connects the body to the circuit board; and
a header disposed above the body such that the body is between the header and the circuit board,
wherein the body and the header form a continuous surface on a first side of the heating element, and the body and the header form a discontinuous surface on a second side of the heating element.

7. The energy storage apparatus of claim 6, wherein the cooling device includes:
a first cooling plate disposed to contact the first side of the heating elements; and
a second cooling plate disposed to contact with the second side of the heating elements,
wherein the first cooling plate is to contact the body and the header of the heating elements, and the second cooling plate is to contact the body of the heating elements.

8. The energy storage apparatus of claim 7, wherein the first cooling plate includes:
a first plate to provide a flow path configured to allow flow of the cooling liquid; and
a first fixing plate configured for coupling the first plate to the heating elements, and
the second cooling plate includes:
a second plate to provide a flow path configured to allow flow of the cooling liquid; and
a second fixing plate configured for coupling the second plate to the heating elements.

9. The energy storage apparatus of claim 8, wherein the first plate and the second plate are disposed in different directions with respect to the heating elements, and the first fixing plate and the second fixing plate are disposed in a same direction with respect to the heating elements.

10. The energy storage apparatus of claim 8, wherein a vertical length of the first plate is greater than a vertical length of the second plate.

11. The energy storage apparatus of claim 8, wherein each of the first plate and the second plate separately includes a first flow path and a second flow path disposed below the first flow path, and each of the first and second flow paths provided by the first plate includes a plurality of flow paths that are vertically spaced apart from each other.

12. The energy storage apparatus of claim 8, wherein the header has a fixing hole, and the first fixing plate has a first hole corresponding to a position to the fixing hole.

13. The energy storage apparatus of claim 12, wherein the second fixing plate has a second hole corresponding to a position of the first hole,
wherein a diameter of the second hole of the second fixing plate is smaller than a diameter of the fixing hole of the header or a diameter of the first hole of the first fixing plate.

14. The energy storage apparatus of claim 13, wherein the first fixing plate and the second fixing plate are disposed to face each other, and the second hole of the second fixing plate is disposed to correspond to a position of the first hole of the first fixing plate.

15. The energy storage apparatus of claim 8, wherein the first fixing plate and the second fixing plate are configured to alter shape when a given pressure is applied.

16. The energy storage apparatus of claim 12, wherein a portion of the first fixing plate having the first hole is configured to have the portion of the first fixing plate move into the fixing hole based on pressing by a jig.

17. The energy storage apparatus of claim 1, wherein the cooling device includes:
a cooling plate to contact each of the plurality of heating elements, and having a flow path configured to allow flow of the cooling liquid; and
a heat sink disposed on a side of the cooling plate and configured to release heat transferred from the cooling plate.

18. The energy storage apparatus of claim 17, wherein the cooling plate includes:
a first cooling plate to contact a first side of each of the plurality of heating elements; and
a second cooling plate to contact a second side of each of the plurality of heating elements, and
the heat sink is to be attached to the first cooling plate and is to be attached to the second cooling plate.

19. The energy storage apparatus of claim 17, wherein the heat sink includes:
a contact plate to contact the cooling plate; and
a plurality of heat radiating fins that protrude from an outer surface of the contact plate,
the first cooling plate includes:
a first plate having a flow path configured to allow flow of the cooling liquid; and
first fixing plate configured for coupling the first plate to the heating elements, and
the second cooling plate includes:
a second plate having a flow path configured to allow flow of the cooling liquid; and
a second fixing plate configured for coupling the second plate to the heating elements,
wherein the plurality of heat radiating fins are disposed at least in an area corresponding to where the contact plate contacts the first plate or the second plate.

20. An energy storage apparatus comprising:
a battery pack configured to support a plurality of battery cells;
a power converter configured to charge or discharge the plurality of battery cells;
a pump configured to provide a cooling liquid to the battery pack or the power converter; and
a heat radiator configured to dissipate heat from the cooling liquid flowing from the battery pack or the power converter,
wherein the power converter includes:
a circuit board;
a plurality of heating elements disposed on a side of the circuit board;
a cooling plate to contact the plurality of heating elements, and provide at least one flow path configured to allow flow of the cooling liquid; and
a heat sink disposed on an outer surface of the cooling plate, and configured to dissipate heat from the cooling plate,
wherein the heat sink is configured such that the cooling plate is to directly contact the heating elements.
